(19) United States
(12) Patent Application Publication
(10) Pub. No.: US 2010/0277098 A1
(43) Pub. Date: Nov. 4, 2010

(54) LED LIGHTING SYSTEM

(76) Inventor: Timothy Sarna, Delaware, OH (US)

Correspondence Address: ELEY LAW FIRM CO., 7870 OLENTANGY RIVER RD, SUITE 311, COLUMBUS, OH, 43235, US

(21) Appl. No.: 12/769,760

(22) Filed: Apr. 29, 2010

Related U.S. Application Data
(60) Provisional application No. 61/174,492, filed on Apr. 30, 2009.

(51) Int. Cl. H05B 37/02; H01L 33/00; H01J 9/24

(52) U.S. Cl. 315/294; 362/555; 445/23

(57) ABSTRACT

An LED lighting system having a plurality of light rods. Each light rod includes a generally hollow, longitudinal housing and a plurality of light emitting diodes disposed within the housing. Electrical wiring extends between the light emitting diodes, the light emitting diodes being electrically coupled to the wiring. A male electrical connector terminates and seals a first end of the housing and is electrically coupled to the wiring. A female electrical connector terminates and seals a second, opposing end of the housing and is also electrically coupled to the wiring. The light rods are electrically and mechanically joined together by coupling the male electrical connectors of the light rods to female connectors of adjacent light rods.

This application claims priority to U.S. provisional patent application No. 61/174,492, filed Apr. 30, 2009, the contents of which are hereby incorporated by reference.

### FIELD

The present invention relates generally to lighting systems, in particular to a reconfigurable lighting system comprising light emitting diodes (LEDs) and is usable for holiday lighting, among other uses.

### BACKGROUND

Light strings are commonly used for both indoor and outdoor decorative lighting. For example, light strings often adorn commercial buildings such as restaurants, adding to the decor. Light strings are also used to add a festive touch to both commercial and residential patios, gazebos, party tents and the like. Similarly, light strings are often placed about buildings and other structures during holidays, such as at Christmas. Light strings typically comprise a flexible electrical cable having a number of spaced-apart electrical sockets with incandescent lamps.

Although effective for their intended purpose, presently available light strings suffer from a number of drawbacks. For example, incandescent lamps have a relatively short useful life, necessitating regular replacement. Consequently, a supply of spare lamps must be kept on hand. In addition, with some types of light strings a failure of a single lamp will cause all of the lamps in the string to stop working. This makes locating the failed lamp difficult and time-consuming. Replacement of a failed lamp can also be very inconvenient, particularly if the light string is mounted in a relatively inaccessible place, such as along the roof of a building structure.

Another drawback of present light strings is that they are typically provided in fixed, predetermined lengths. Although light strings may be coupled together in series fashion to increase their overall length, all too often an installer ends up with a light string that is either too short or too long for a particular installation. In addition, the process of attaching the light strings to a structure can be physically challenging and, in some cases, dangerous because of the heights involved.

Various devices are used to attach string lights to a structure. These include using hooks, clips and staples to name a few, typically placed at intervals of about every one to two feet. While these devices do work, they can be unsightly. Furthermore, repeated use of fasteners such as staples and hooks when periodically installing and removing light strings (such as with seasonal lighting) can begin to destroy the building material of the structure.

There is a need for a lighting system that does not require regular maintenance, can be easily configured for a given installation, and that can be easily attached and detached from a structure.

### SUMMARY

An LED lighting system is disclosed according to an embodiment of the present invention. The LED lighting system includes “light rods” comprising a housing made of a longitudinal, clear plastic material. A male electrical connector and a female electrical connector terminate and seal opposing ends of the housing. Electrical wiring extends between the male and the female connectors, within the housing. A plurality of spaced-apart LEDs are disposed within the housing and are in electrical communication with the wiring. The light emitting diodes have a long useful life, essentially eliminating the need for periodic replacement. In addition, the light rods may be provided in various lengths and can be joined together with the connectors, allowing an installer to custom-configure the lighting system for the needs of a particular installation. In some embodiments the light rods may be made sufficiently rigid so that they are easily attachable to a support structure. The rigid light rods require fewer fasteners than traditional string lights and can easily be assembled, disassembled and stored.

In one embodiment of the present invention an LED lighting system comprises a plurality of light rods. Each light rod includes a generally hollow, longitudinal housing and a plurality of light emitting diodes disposed within the housing. Electrical wiring extends between the light emitting diodes, the light emitting diodes being electrically coupled to the wiring. A male electrical connector terminates and seals a first end of the housing and is electrically coupled to the wiring. A female electrical connector terminates and seals a second, opposing end of the housing and is also electrically coupled to the wiring. The rigid light rods are electrically and mechanically joined together by coupling the male electrical connectors of the light rods to female connectors of adjacent light rods.

In another embodiment of the present invention an LED lighting system comprises a plurality of light rods that are joined together. Each light rod includes a generally hollow, longitudinal housing. A plurality of light emitting diodes are disposed within the housing. Electrical wiring extends between the light emitting diodes, the light emitting diodes being electrically coupled to the wiring. A male electrical connector terminates and seals a first end of the housing and is electrically coupled to the wiring. A female electrical connector terminates and seals a second, opposing end of the housing and is also electrically coupled to the wiring. A cover cap or plug closes off an exposed female electrical connector of the joined light rods. A power supply is electrically and mechanically coupled to an exposed male electrical connector of the joined light rods. At least one support member is configured to detachably join the light rods to a structure. At least one endcap is configured to further detachably join the light rods to the structure. The light rods are electrically and mechanically joined together by coupling the male electrical connectors of the light rods to female connectors of adjacent light rods.

### BRIEF DESCRIPTION OF THE DRAWINGS

Further features of the inventive embodiments will become apparent to those skilled in the art to which the embodiments relate from reading the specification and claims with reference to the accompanying drawings, in which:

FIG. 1 is a light rod according to an embodiment of the present invention;

FIG. 2 shows a plurality of the light rods of FIG. 1 being coupled together;

FIG. 3 is a flexible light rod according to another embodiment of the present invention;

FIG. 4 is a power cable harness for use with an LED lighting system according to an embodiment of the present invention;

FIG. 5 is a support member for use with an LED lighting system according to an embodiment of the present invention;

FIG. 6 shows a lighting system assembled to a building structure according to an embodiment of the present invention;

FIGS. 7A and 7B show a lighting system being installed to a building structure according to an embodiment of the present invention; and

FIG. 8 shows a radial lighting system configured for a patio umbrella according to another embodiment of the present invention.

### DETAILED DESCRIPTION

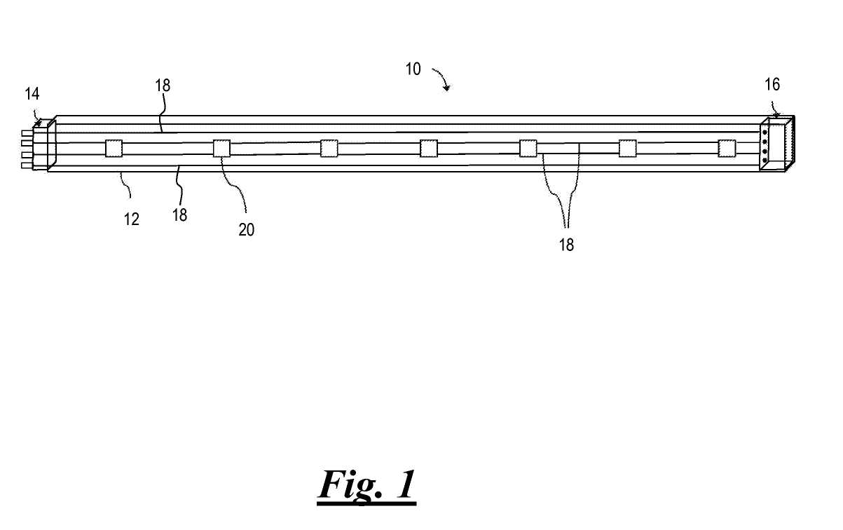

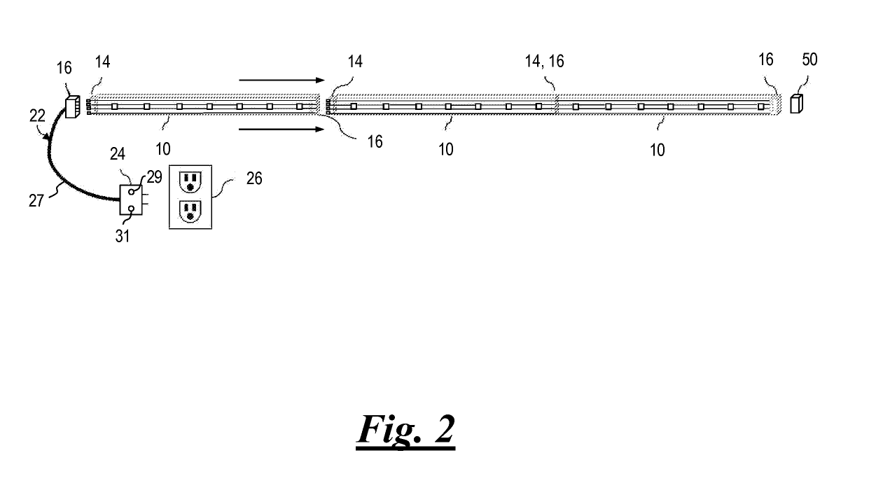

The general arrangement of a light rod 10 for use with an LED lighting system is shown in FIG. 1. Light rod 10 includes a longitudinal, generally hollow housing 12. A male electrical connector 14 and a female electrical connector 16 are at opposing ends of housing 12, each terminating and sealing off an end of the housing. Electrical wiring 18 extends between male connector 14 and female connector 16. A plurality of spaced-apart light emitting diodes 20 are disposed within housing 12 and are electrically coupled to wiring 18 in at least one of series, parallel and series-parallel with respect to each other. Light rod 10 may be provided in any convenient length of combinations of lengths such as, without limitation, 1-, 2- and 4-foot lengths. A group of light rods 10 may be mechanically and electrically coupled together in series fashion by coupling the male connector 14 of a light rod to the female connector 16 of an adjacent light rod, as shown in FIG. 2.

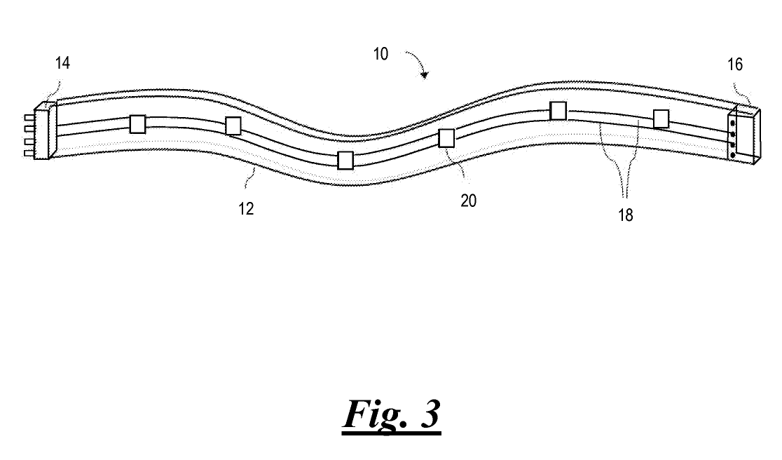

Housing 12 is generally hollow and may be made from any suitable material, such as clear or translucent plastic or glass. In some embodiments housing 12 is generally rectangular in section, although other shapes such as square, tubular (i.e., circular or oval) and triangular are within the scope of the invention. In some embodiments of the present invention housing 12 is generally rigid, although in other embodiments the housing may be flexible, as shown in FIG. 3, allowing the light rod 10 to be formed around corners or to be formed into a desired shape, such as arches, circles, spirals and alphabetic characters to name a few examples. Flexible embodiments of housing 12 may exhibit a “memory effect,” being biased to return to a predetermined shape when in an unrestrained condition. Alternatively, flexible housings 12 may be configured to retain a shape after being formed by a user, with or without the aid of an additional structure or structures (not shown) within the housing.

Male connector 14 and female connector 16 may be any type of selectably coupled and detachable electrical connectors suitable for the environment expected of an LED lighting system, and which provides the requisite number of electrical circuit connections. Male connector 14 and female connector 16 preferably include mechanical retention features that act to keep a set of coupled male and female connectors from becoming unintentionally disengaged. Such retention features may include, without limitation, complementary threads, bayonets, locking tabs, friction elements, snaps and biased members. In some embodiments male connector 14 and female connector 16 may be weatherproof-type connectors.

Light emitting diodes 20 may be provided in any select color or combinations of colors of emitted light including, without limitation, white (e.g., blue/white or warm white), red, blue and green. Light emitting diodes 20 have a significantly longer useful life in comparison to incandescent lamps, and they do not require significant amounts of energy for operation. Light emitting diodes 20 may each include internal current-limiting devices such as resistors (not shown). Alternatively, in some embodiments of the present invention each light rod 10 may include a current-limiting device.

A power supply 22 is shown in FIG. 2. Power supply 22 includes a power converter 24 that converts an external source of power 26 to a voltage and/or current that is compatible with LEDs 20. Power supply 22, which may be weatherproof, also includes a female connector 16 at a distal end of a wiring cable 27, the female connector being configured to couple to a male connector 14 of a light rod 10. Power supply 22 may further include one or more user-adjusted power controls 29 to tailor the voltage and/or current output of the power supply to match the number of light rods 10 connected thereto. In some embodiments of the present invention power supply 22 may also include one or more user-adjusted output controls 31 to operate LEDs 20 in a predetermined manner, such as dimming or flashing one or more LEDs or light rods 10, or turning the LEDs or light rods on and off in a sequential manner. The flashing or sequence rate or pattern may also be adjustable by controls 29, 31, if desired.

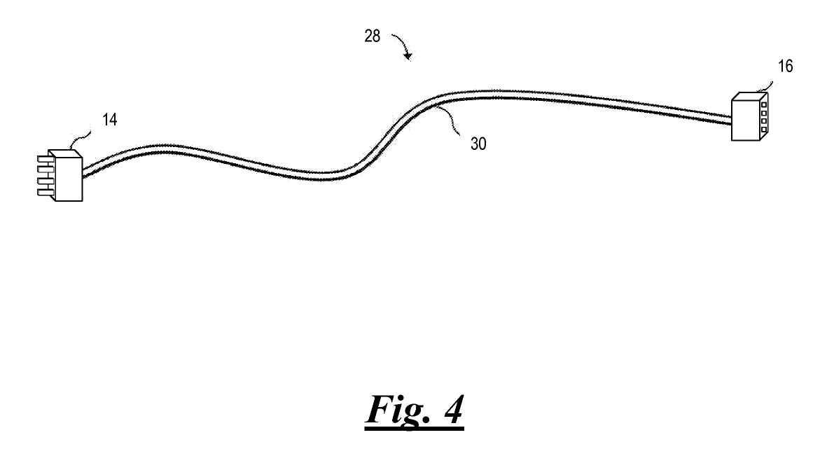

A power cable harness 28 is shown in FIG. 4 according to an embodiment of the present invention. Power cable harness 28 includes flexible electrical wiring 30 extending between a male connector 14 and a female connector 16. Power cable harness 28 may be used to electrically couple together a pair of adjacent light rods 10, such as around a corner of a building structure.

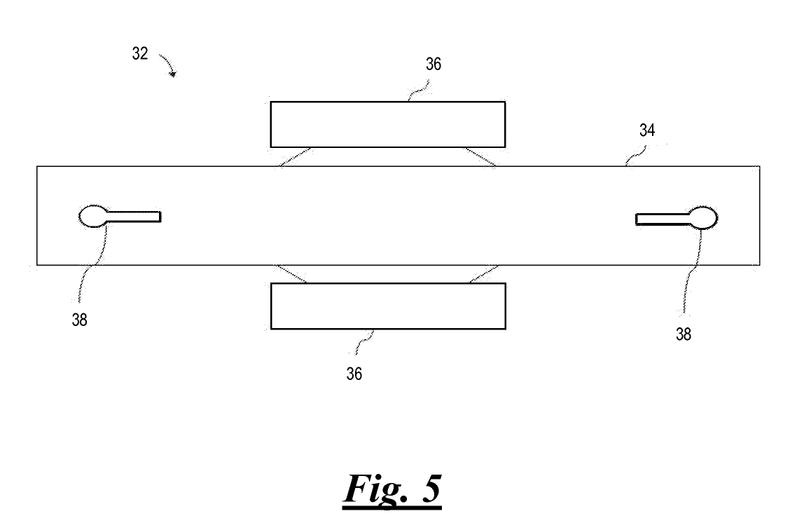

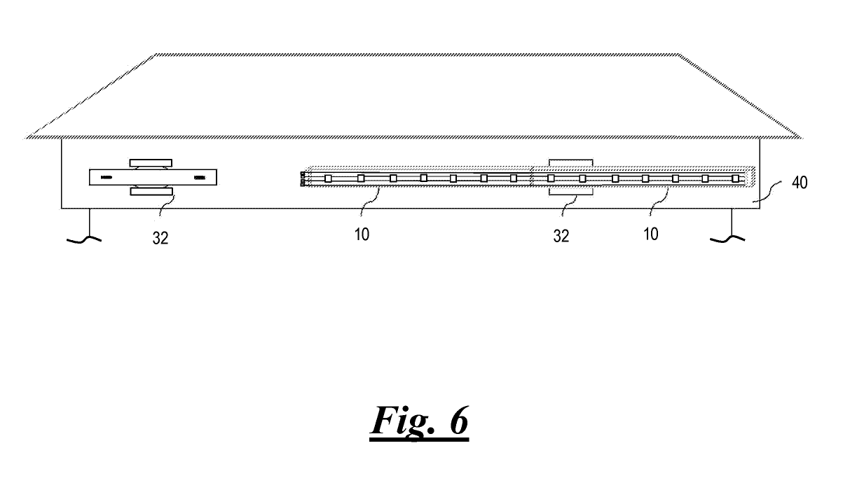

A support member 32 is shown in FIG. 5 according to an embodiment of the present invention. Support member 32 includes a bracket 34 and a pair of spaced-apart, resilient grips 36 configured to detachably secure a light rod 10 therebetween. Bracket 34 further includes one or more mounting apertures 38, which may be keyhole-shaped, for mounting the support member 32 to a support structure such as a building 40 with fasteners such as nails or screws, as generally shown in FIG. 6. Support member 34 may optionally be provided in a predetermined color, which may be molded-in or may be a finish. Alternatively, support member 32 may be painted to match building 40.

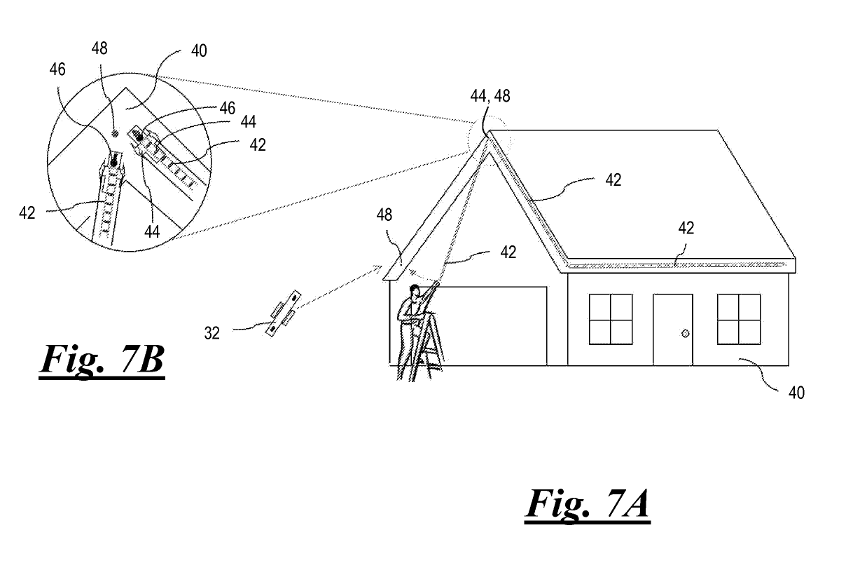

With reference to FIGS. 7A and 7B, in some embodiments of the present invention a group 42 comprising a plurality of light rods 10 may include an endcap 44 having at least one mounting aperture 46. Mounting aperture 46 may be keyhole-shaped, if desired. Endcaps 44 may be coupled to a support 48, such as a fastener secured to a building 40. In this way a group 42 of light rods 10 may be easily attached to a portion of building 40 that is not otherwise easily accessible. In many cases a group 42 of light rods 10 may be attached to building 40 from the ground or a low ladder, as shown in FIG. 7A. An opposing end of the group 42 of light rods 10 may be secured to a support member 32, as also shown in FIG. 7A.

With reference to FIGS. 1 through 7B together, in use groups 42 of light rods 10 are formed by assembling together light rods 10 of a select combination of lengths for the structure to which they are to be attached. The groups 42 are then attached to a support structure 40 with support members 32, endcaps 44 and fasteners 48 as shown in FIGS. 6, 7A and 7B. Groups 42 may be coupled together with power cable harnesses 28 (FIG. 4) as desired. Power is supplied to the assembled system of light rods 10 by a power supply 22 coupled to an open male connector 14 of a first end light rod 10 of groups 42 and connected to a power source 26. A cover cap or plug 50 (FIG. 2) may be detachably coupled to an open female connector 16 of a second, opposing end light rod 10 of the group or groups 42 to protect the female connector from exposure to the environment. The lighting system may be easily removed from the support structure and disassembled for storage when not needed.

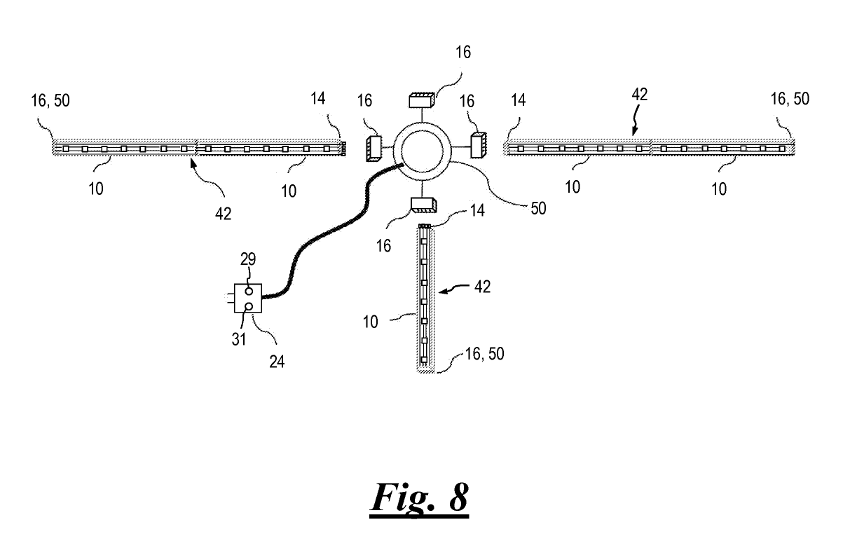

With reference to FIG. 8, in one embodiment of the present invention groups 42 comprising light rods 10 may be configured for installation to structures radially, such as for use with patio umbrellas. A ring support 52 having a set of flexibly-attached female connectors 16 is secured to the tip of an umbrella (not shown). The groups 42 of light rods 10 are routed along spines of the umbrella and secured thereto in any suitable manner. A power converter 24 is wired to ring support 52 and to female connectors 16. An open male connector 14 of each of groups 42 is coupled to a corresponding female connector 16, providing electrical power to the groups. A cover cap 50 (FIG. 2) may be detachably coupled to an open female connector 16 of an opposing end light rod 10 of each of the groups 42 to protect the female connector from exposure to the environment.

In another embodiment of the present invention light rods 10 may be installed under a cabinet or other fixture to provide a hidden light source. In still another embodiment the light rods 10 are arranged into decorative “icicle” shapes for attachment to a structure, for example, that may likewise be disassembled or folded/collapsed for storage.

The present invention provides a number of advantages over current lighting systems. The system described herein is easily installed or removed, and disassembles into components that are small in size for easy storage. The system also eliminates the need for exposed wiring and lamps that are easily tangled or damaged. In addition, the system may be easily tailored for installation to structures having varying sizes and shapes. Example structures include, without limitation, houses, barns, tents and gazebos.

From the above description of the invention, those skilled in the art will perceive improvements, changes, and modifications in the invention. Such improvements, changes, and modifications within the skill of the art are intended to be covered.

What is claimed is:

1. An LED lighting system comprising:
a plurality of light rods, each light rod including:
a generally hollow, longitudinal housing;
a plurality of light emitting diodes disposed within the housing;
electrical wiring extending between the light emitting diodes, the light emitting diodes being electrically coupled to the wiring;
a male electrical connector terminating and sealing a first end of the housing, the male electrical connector being electrically coupled to the wiring; and
a female electrical connector terminating and sealing a second, opposing end of the housing, the female electrical connector being electrically coupled to the wiring,
the light rods being electrically and mechanically joined together by coupling the male electrical connectors of the light rods to female connectors of adjacent light rods.

2. The LED lighting system of claim 1 wherein the housing is one of rectangular, square, tubular and triangular in section.

3. The LED lighting system of claim 1 wherein the housing is one of clear and translucent.

4. The LED lighting system of claim 1 wherein the housing is one of rigid and flexible.

5. The LED lighting system of claim 4 wherein the flexible housing is biased to a predetermined shape when in an unrestrained condition.

6. The LED lighting system of claim 4 wherein the flexible housing is formable to a desired shape, the flexible housing retaining the shape once formed.

7. The LED lighting system of claim 1 wherein the light emitting diodes emit light that is at least one of white, red, blue and green in color.

8. The LED lighting system of claim 1, further including a cover cap closing off an exposed female electrical connector of the joined light rods.

9. The LED lighting system of claim 1, further including a power supply electrically and mechanically coupled to an exposed male electrical connector of the joined light rods.

10. The LED lighting system of claim 9 wherein the power supply further comprises a user-adjusted power control to adjust at least one of a voltage and current output of the power supply.

11. The LED lighting system of claim 9 wherein the power supply further comprises a user-adjusted output control to adjust at least one of dimming, flashing and sequencing of the light emitting diodes.

12. The LED lighting system of claim 1, further including at least one flexible power cable harness extending between adjacent light rods, the power cable harness mechanically and electrically coupling together said adjacent light rods.

13. The LED lighting system of claim 1, further including at least one support member configured to detachably join the light rods to a structure.

14. The LED lighting system of claim 13 wherein the support member further comprises a mounting aperture to detachably join the support member to the structure.

15. The LED lighting system of claim 14 wherein the mounting aperture is keyhole-shaped.

16. The LED lighting system of claim 13 wherein the support member further comprises a pair of spaced-apart, resilient grips to detachably secure a light rod therebetween.

17. The LED lighting system of claim 1, further including at least one endcap configured to detachably join the light rods to a structure.

18. An LED lighting system comprising:
a plurality of light rods joined together, each light rod including:
a generally hollow, longitudinal housing, the housing being one of clear or translucent;
a plurality of light emitting diodes disposed within the housing;
electrical wiring extending between the light emitting diodes, the light emitting diodes being electrically coupled to the wiring;
a male electrical connector terminating and sealing a first end of the housing, the male electrical connector being electrically coupled to the wiring;
a female electrical connector terminating and sealing a second, opposing end of the housing, the female electrical connector being electrically coupled to the wiring;
a cover cap closing off an exposed female electrical connector of the joined light rods;
a power supply electrically and mechanically coupled to an exposed male electrical connector of the joined light rods;
at least one support member configured to detachably join the light rods to a structure; and
at least one endcap configured to detachably join the light rods to the structure,
the light rods being electrically and mechanically joined together by coupling the male electrical connectors of the light rods to female connectors of adjacent light rods.

19. The LED lighting system of claim 18, further including at least one flexible power cable harness extending between adjacent light rods, the power cable harness mechanically and electrically coupling together said adjacent light rods.

20. A method for making an LED lighting system, comprising the steps of:
providing a plurality of light rods, each light rod including the steps of:
providing a generally hollow, longitudinal housing;
disposing a plurality of light emitting diodes within the housing;
extending electrical wiring between the light emitting diodes, the light emitting diodes being electrically coupled to the wiring;
terminating and sealing a first end of the housing with a male electrical connector, the male electrical connector being electrically coupled to the wiring; and
terminating and sealing a second, opposing end of the housing with a female electrical connector, the female electrical connector being electrically coupled to the wiring, and
electrically and mechanically joining together the light rods by coupling the male electrical connectors of the light rods to female connectors of adjacent light rods.
